(19) United States
(12) Patent Application Publication
(10) Pub. No.: US 2025/0005228 A1
(43) Pub. Date: Jan. 2, 2025

(54) INFORMATION PROCESSING DEVICE AND METHOD

(71) Applicant: HITACHI, LTD., Tokyo (JP)

(72) Inventors: Tetsushi ONO, Tokyo (JP); Masashi YAMAMOTO, Tokyo (JP); Osamu TOMOBE, Tokyo (JP); Tsutomu KAWAMURA, Tokyo (JP)

(21) Appl. No.: 18/698,810

(22) PCT Filed: Oct. 6, 2022
(86) PCT No.: PCT/JP2022/037452

§ 371 Date: Apr. 5, 2024

(30) Foreign Application Priority Data
Oct. 25, 2021 (JP) 2021-173594

(51) Int. Cl. G06F 30/20

(52) U.S. Cl. CPC G06F 30/20

(57) ABSTRACT

An off-grid area selection device that selects an area in which an off-grid in a power distribution system having a plurality of switches arranged therein can be constructed, and an off-grid area selection method executed in the off-grid area selection device are configured to select an area in which an off-grid in the power distribution system can be constructed based on each piece of information regarding a load capacity and a power supply facility for each switch section and facility information of the power distribution system, simulate system stability in the selected area, and determine whether or not the area can comply with a system operation constraint of the power distribution system.

### TECHNICAL FIELD

The present invention relates to an information processing device and a method, and is suitably applied to an off-grid area selection device that selects an area in which an off-grid in a power distribution system can be constructed.

### BACKGROUND ART

Conventionally, as one of system devices constituting a power distribution system, there is a switch that opens and closes a passage of electricity. Since switches are generally installed every several hundred meters to several kilometers, the number of switches installed in the entire power distribution system is enormous. Therefore, there are an enormous number of system topologies that can be taken by the power distribution system, that is, combinations of switch states (open or closed) of the switches.

The switches are divided into two types of switches, a manual switch and a remote control switch, according to the operation method. The manual switch is a switch that is manually opened and closed, and the remote control switch is a switch that can be remotely opened and closed by a power distribution automation system of a power distribution company (for example, an electric power company). In recent years, application of the remote control switch to another purpose has been sought due to a high degree of freedom that a desired system topology can be instantaneously constructed by a remote opening/closing operation among an enormous number of system topology candidates. One of them is off-grid construction.

Here, “off-grid construction” refers to construction of an area independently operated as a microgrid by separating some areas of a power distribution system from other power distribution systems by a switch in normal or emergency times. In the off-grid area (hereinafter, referred to as off-grid area), it is necessary to secure system stability such as frequency. Further, as the power source in the off-grid area, in addition to the conventional power generator, a power generator that generates renewable energy such as solar power generation or wind power generation, a power-source vehicle, a system battery, an electric vehicle, and the like can be considered.

As an advantage of constructing the off-grid area in normal times, there is mitigation of system congestion by promoting local production and local consumption of power. In addition, the construction of an off-grid area having a high renewable energy generation ratio is advantageous from the viewpoint of regional branding, induction of bases of companies aiming at RE100 (Renewable Energy 100%), and the like.

In addition, as an advantage of constructing the off-grid area in emergency times such as when a typhoon is approaching or an earthquake occurs, there is a reduction in a power outage time due to power supply by the off-grid area alone, that is, an improvement in system resilience even when the surrounding power system fails.

Furthermore, off-grid construction has attracted attention as an effective use measure of a distributed power supply (hereinafter, referred to as DER (Distributed Energy Resources)) connected to a power distribution system. It is considered that the DER can be remotely commanded and controlled by a DER management system (DERMS) of a power distribution company in the future. DMRMS contributes to maintaining system stability within the off-grid area and to quick construction of the off-grid area.

On the other hand, since there are an enormous number of system topology candidates that can be taken by the power distribution system as described above, there are also an enormous number of candidates for a combination of what switch section (section sandwiched between adjacent switches) is selected as the off-grid area. From among these candidates, it is necessary to determine a combination of switch sections to be turned into an off-grid in consideration of whether or not system stability such as frequency can be secured.

As one of the techniques for operating the off-grid area, PTL 1 discloses a technique for determining a control amount of a power conditioning subsystem (PCS) of renewable energy based on a state of charge (SoC) of a battery in an individual operation of a microgrid after disconnection to solve a problem that there is a possibility that the PCS is controlled independently of the SoC of the battery, and the storage battery is fully charged/overdischarged, which hinders long-term individual operation.

### CITATION LIST

### Patent Literature

PTL 1: JP 2021-40428 A

### SUMMARY OF INVENTION

### Technical Problem

However, PTL 1 does not include a mechanism for selecting an area in which the microgrid is individually operated. Therefore, if such an area is to be selected using the technology disclosed in PTL 1, it is necessary to perform the simulation disclosed in PTL 1 for all of the enormous number of candidates, and there is a problem that enormous calculation time is required.

Although it is conceivable to formulate the selection of the off-grid area as an optimization problem, system stability such as frequency cannot be simulated by optimization calculation. For this reason, in the selection of such an area only by optimization calculation, for example, a candidate having a problem in system stability such as a frequency cannot be maintained cannot be excluded, and such an area may be erroneously selected.

The present invention has been made in view of the above points, and an object of the present invention is to propose an information processing device and a method capable of selecting an off-grid area in consideration of system stability in a short time.

### Solution to Problem

In order to solve such a problem, the present invention provides an information processing device that selects an area in which an off-grid in a power distribution system having a plurality of switches arranged therein is constructible, the information processing device including: an off-grid area selection unit that selects an area in which an off-grid in the power distribution system is constructible based on each piece of information regarding a load capacity and a power supply facility for each switch section and facility information of the power distribution system; and a system stability simulation unit that simulates system stability in the area selected by the off-grid area selection unit and determines whether or not the area is able to comply with a system operation constraint of the power distribution system.

Furthermore, the present invention provides an information processing method executed in an off-grid area selection device that selects an area in which an off-grid in a power distribution system having a plurality of switches arranged therein is constructible, the method including: a first step of selecting an area in which an off-grid in the power distribution system is constructible based on each piece of information regarding a load capacity and a power supply facility for each switch section and facility information of the power distribution system; and a second step of simulating system stability in the selected area and determining whether or not the area is able to comply with a system operation constraint of the power distribution system.

According to the information processing device and the method of the present invention, system stability can be simulated only for an area where an off-grid can be constructed.

### Advantageous Effects of Invention

According to the present invention, it is possible to realize an information processing device and a method capable of selecting an off-grid area in consideration of system stability in a short time.

### BRIEF DESCRIPTION OF DRAWINGS

FIG. 1 is a block diagram illustrating a configuration example of an off-grid area selection device.

FIG. 2 is a block diagram illustrating a logic configuration example of the off-grid area selection device according to a first embodiment.

FIG. 3(A) is a table illustrating a configuration example of power distribution system configuration information, and FIG. 3(B) is a table illustrating a configuration example of switch configuration information.

FIG. 4 is a conceptual diagram for explaining an off-grid area.

FIG. 5 is a table illustrating a configuration example of load prediction information.

FIG. 6 is a table illustrating a configuration example of renewable energy output prediction information.

FIG. 7 is a table illustrating a configuration example of a system stability violation amount table.

FIGS. 8(A) and 8(B) are graphs used for explaining a system stability constraint.

FIG. 9 is a table illustrating a configuration example of a sensitivity information table.

FIG. 10 is a flowchart illustrating a processing procedure of off-grid area selection processing.

FIG. 11 is a block diagram illustrating a logical configuration example of an off-grid area selection device according to a second embodiment.

### DESCRIPTION OF EMBODIMENTS

Hereinafter, an embodiment of the present invention will be described in detail with reference to the drawings.

### (1) First Embodiment

### (1-1) Configuration of Off-Grid Area Selection Device According to Present Embodiment

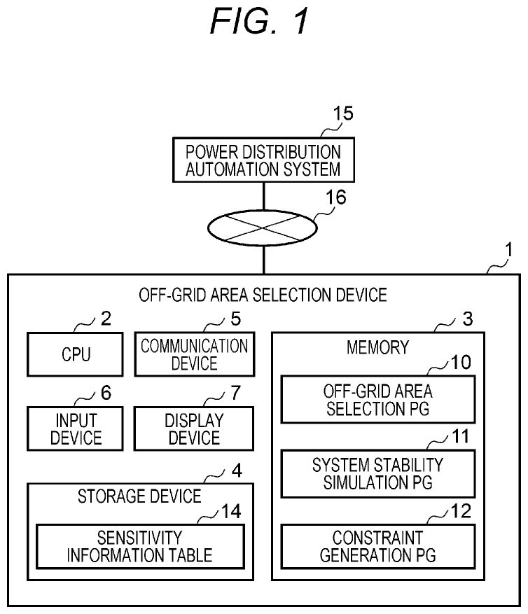

In FIG. 1, reference numeral 1 generally denotes an off-grid area selection device according to the present embodiment. The off-grid area selection device 1 is an information processing device equipped with a function of selecting an area (off-grid area) in which an off-grid in a power distribution system (not illustrated) can be constructed, and includes a general-purpose server device including a central processing unit (CPU) 2, a memory 3, a storage device 4, a communication device 5, an input device 6, and a display device 7.

The CPU 2 is a processor that controls the entire operation of the off-grid area selection device 1. In addition, the memory 3 includes, for example, a volatile semiconductor memory, and is used as a work memory of the CPU 2. The memory 3 temporarily stores various programs read from the storage device 4 when the off-grid area selection device 1 is activated or when necessary. An off-grid area selection program 10, a system stability simulation program 11, and a constraint generation program 12 to be described later are also read from the storage device 4 when necessary, and stored and held in the memory 3.

The storage device 4 includes, for example, a large-capacity nonvolatile storage device such as a hard disk device or a solid state drive (SSD), and stores various programs and various data that needs to be stored for a long period of time. A sensitivity information table 14 to be described later is also stored and held in the storage device 4.

The communication device 5 is an interface device for communicating with a power distribution automation system 15 of a power distribution company, a server device on which a DERMS is mounted, or the like via a network 16. The input device 6 includes a keyboard, a mouse, and the like, and is used by the operator to input various instructions and information. Furthermore, the display device 7 includes, for example, a liquid crystal display, an organic electro-luminescence (EL) display, or the like, and is used to display various graphical user interface (GUI) screens and various types of information.

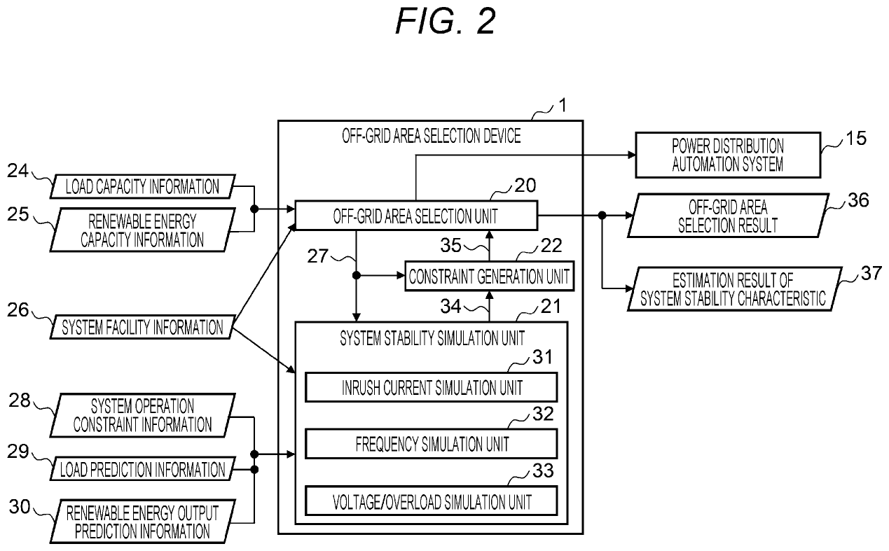

FIG. 2 illustrates a logical configuration of the off-grid area selection device 1. As illustrated in FIG. 2, the off-grid area selection device 1 includes an off-grid area selection unit 20, a system stability simulation unit 21, and a constraint generation unit 22.

The off-grid area selection unit 20 is a functional unit implemented by the CPU 2 (FIG. 1) of the off-grid area selection device 1 executing the off-grid area selection program 10 stored in the memory 3 (FIG. 1). The off-grid area selection unit 20 acquires load capacity information 24, renewable energy capacity information 25, and system facility information 26 from the power distribution automation system 15 (FIG. 1) of the power distribution company, and selects an area where an off-grid in the power distribution system can be constructed using the acquired information. Then, the off-grid area selection unit 20 outputs the selection result as an off-grid area selection proposal 27 to the system stability simulation unit 21 and the constraint generation unit 22.

Here, the load capacity information 24 is a maximum value of a load capacity for each switch section, which is a section between switches installed every several hundred meters to several kilometers in the power distribution system, that is, a total capacity of all loads existing in the switch section for each switch section. The “maximum value of the total capacity of the load” may be statistically obtained or based on the contract contents with each power consumer.

Further, the renewable energy capacity information 25 is the maximum value of the capacity of the renewable energy for each switch section, that is, the total capacity of the renewable energy output from the renewable energy power generation facility or the like existing in the switch section for each switch section. The “maximum value of the total capacity of the renewable energy” may also be statistically obtained or based on a contract with each renewable energy provider. In addition, the “maximum value of the total capacity of the renewable energy” may be the maximum value of the total capacity including the output from the power generation facility that generates power other than the renewable energy and the output from the distributed power source such as the system storage battery or the power-source vehicle.

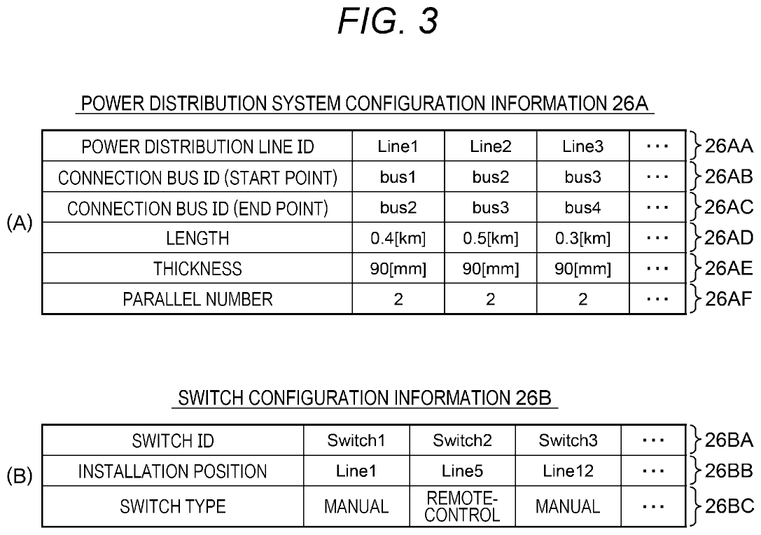

The system facility information 26 is information indicating a configuration of a power distribution system, and includes, for example, power distribution system configuration information 26A as illustrated in FIG. 3(A) and switch configuration information 26B illustrated in FIG. 3(B).

The power distribution system configuration information 26A is information on each power distribution line constituting the power distribution system, and includes power distribution line ID information 26AA, connection bus ID (start point) information 26AB, connection bus ID (end point) information 26AC, length information 26AD, thickness information 26AE, and parallel number information 26AF for each power distribution line.

The “power distribution line ID information” is information indicating an identifier (power distribution line ID) unique to a corresponding power distribution line assigned to the corresponding power distribution line, and the “connection bus ID (start point) information” and the “connection bus ID (end point) information” are information indicating an identifier (connection bus ID (start point), connection bus ID (end point)) of a bus that is a start point or an end point of the power distribution line. It should be noted that the “bus” refers to a vertical line to which some components of a power system such as a generator, a load, or a feeder line are connected. Further, “length information” and “thickness information” are information indicating the length and the thickness of the power distribution line, respectively, and “parallel number information” is information indicating the number of electric wires constituting the power distribution line.

The switch configuration information 26B is information on each switch installed in the power distribution system, and includes switch ID information 26BA, installation position information 26BB, and switch type information 26BC for each switch. The “switch ID information” is information indicating an identifier (switch ID) unique to the corresponding switch assigned to the switch, and the “installation position information” is information indicating an identifier of a power distribution line in which the switch is installed. The “switch type information” is information indicating the type (manual or remote control) of the switch.

Then, based on the acquired load capacity information 24, renewable energy capacity information 25, and system facility information 26, the off-grid area selection unit 20 solves a mathematical programming problem given by, for example, the following Equation:

$$\begin{matrix}[ Math . 1 ] & \\ maximize w1 \times area - w 2 \times y & ( 1 )\end{matrix}$$

to select all the areas (off-grid areas) in which the off-grid satisfying Equation (1) can be constructed in the power distribution system, and output the selection result to the system stability simulation unit 21 and the constraint generation unit 22 as the off-grid area selection proposal 27.

Note that the mathematical programming problem illustrated in Equation (1) is a problem of obtaining “area” that maximizes “w1×area−w2×y”, where area represents the area of the off-grid area (hereinafter, referred to as off-grid area area), y represents the estimated value of the system stability violation amount, and w1 and w2 each represent a weighting coefficient. The value of w2 is sufficiently larger than w1.

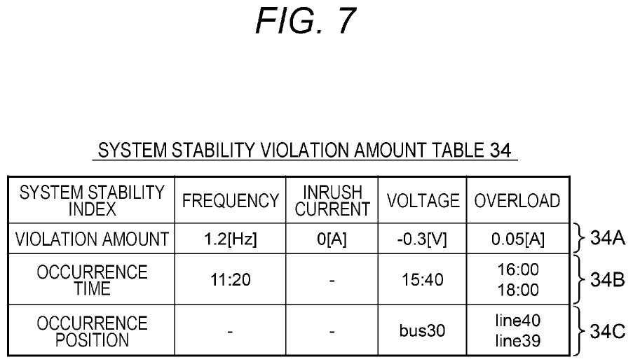

Here, Equation (1) can be regarded as a mathematical programming problem that performs multi-objective optimization of minimizing the estimated value y of the coefficient stability violation amount and maximizing the off-grid area area “area”. In this case, examples of the constraint condition of Equation (1) include a supply and demand balance constraint. In addition, examples of the optimization variable of Equation (1) include an off-grid area area “area”, a combination of switch sections to be turned into an off-grid, a state of each switch, and the like. The estimated value y of the system stability violation amount is an estimated value of the violation amount in a system stability violation amount table 34 described later with reference to FIG. 7, and a preset dummy value is used in the first calculation. The estimation accuracy of the estimated value y can be improved by adding a system stability constraint.

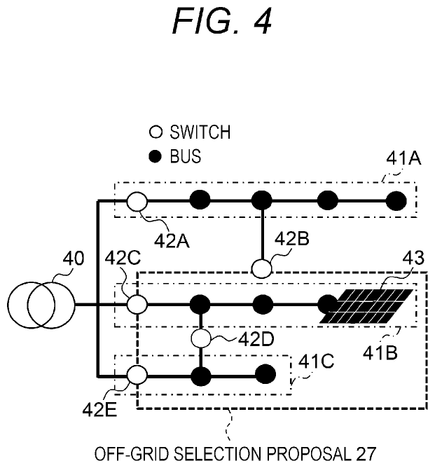

FIG. 4 illustrates an example of the off-grid area selection proposal 27 for one off-grid area obtained by solving the mathematical programming problem of Equation (1). In the power distribution system illustrated in FIG. 4, three power distribution feeders (first to third power distribution feeders) 41A to 41C extend from the power distribution substation 40, and five switches 42A to 42E are installed. The central power distribution feeder (second power distribution feeder) 41B includes a bus to which a solar power generation system 43 is connected. A portion surrounded by a dotted frame is a configuration proposal of one off-grid area, that is, a proposal for selection of one area to be separated from another power distribution system as an off-grid (off-grid area selection proposal 27). If the off-grid area selection proposal 27 is adopted, the switches 42B, 42C, and 42E overlapping with the dotted line are opened, and the other switches 42A and 42D are closed.

In the off-grid area selection proposal 27 illustrated in FIG. 4, the solar power generation system 43 is included in the off-grid area. However, when such an area without a power supply is operated as an off-grid, a movable power supply such as a power-source vehicle or an electric vehicle is used.

Returning to the description of FIG. 2, the system stability simulation unit 21 is a functional unit embodied by the CPU 2 (FIG. 2) of the off-grid area selection device 1 executing the system stability simulation program 11 (FIG. 1) held in the memory 3 (FIG. 1). The system stability simulation unit 21 acquires system operation constraint information 28, load prediction information 29, and renewable energy output prediction information 30 from an external system (FIG. 1) such as the power distribution automation system 15.

The system operation constraint information 28 is information regarding a constraint (hereinafter, referred to as system operation constraint) to be observed in operating the power distribution system, for example, the frequency of the current and voltage flowing through the power distribution system is 49 Hz or more and 51 Hz or less, and the voltage flowing through the power distribution system is 0.93 pu or more and 1.07 pu or less.

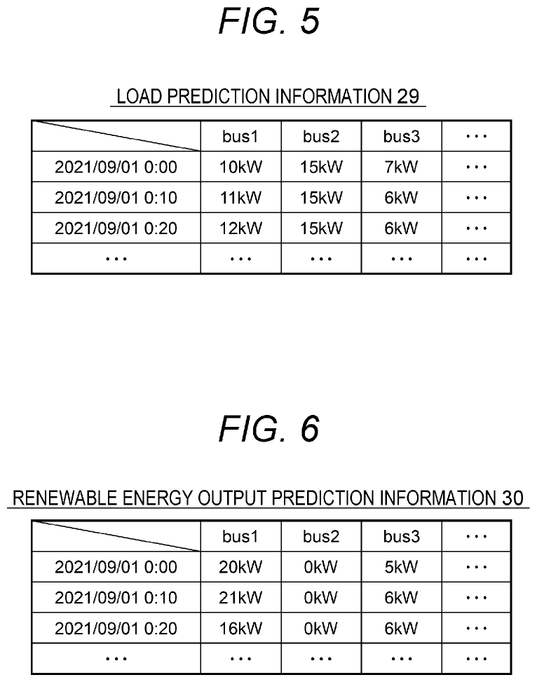

Further, the load prediction information 29 is, for example, as illustrated in FIG. 5, information indicating a prediction value of the load capacity for each predetermined time in each bus. Further, as illustrated in FIG. 6, for example, the renewable energy output prediction information 30 is information indicating a prediction value of the power generation amount of the renewable energy for each predetermined time in each bus. FIGS. 5 and 6 illustrate the case where the time interval is 10 minutes, but other time intervals may be used.

Based on the acquired system operation constraint information 28, load prediction information 29, and renewable energy output prediction information 30, and the off-grid area selection proposal 27 given from the off-grid area selection unit 20, the system stability simulation unit 21 executes various simulations regarding the system stability for one or a plurality of off-grid areas selected by the off-grid area selection unit 20.

In practice, the system stability simulation unit 21 includes an inrush current simulation unit 31, a frequency simulation unit 32, and a voltage/overload simulation unit 33.

Then, the inrush current simulation unit 31 executes a simulation regarding an inrush current in the off-grid area for each off-grid area selected by the off-grid area selection unit 20. In addition, the frequency simulation unit 32 executes simulations regarding frequency fluctuations in these off-grid areas, and the voltage/overload simulation unit 33 executes simulations regarding voltage fluctuations and overloads in these off-grid areas.

Then, when a simulation result that violates the system operation constraint is obtained by each simulation in the inrush current simulation unit 31, the frequency simulation unit 32, and the voltage/overload simulation unit 33, the system stability simulation unit 21 stores the content of each off-grid area for which such a simulation result is obtained in one system stability violation amount table 34 and outputs the content to the constraint generation unit 22.

FIG. 7 illustrates a configuration example of the system stability violation amount table 34 for one off-grid area. As illustrated in FIG. 7, the system stability violation amount table 34 includes a violation amount field 34A, an occurrence time field 34B, and an occurrence position field 34C for four items (system stability indexes) of “frequency”, “inrush current”, “voltage”, and “overload” which are indexes (hereinafter, referred to as system stability indexes) for determining the system stability. Then, the violation amount against the system operation constraint of the corresponding system stability index is stored in the violation amount field 34A, the occurrence time is stored in the occurrence time field 34B, and the occurrence position is stored in the occurrence position field 34C.

Since the frequency is constant regardless of the position, the occurrence position field 34C for the frequency violation may be blank. For the system stability index (“inrush current” in the example of FIG. 7) in which no violation occurs, both the occurrence time and the occurrence position may be left blank. Further, when the violation occurs at a plurality of times and/or positions in each system stability index, the violation amount, the occurrence time, and the occurrence position may be defined as an array or a list, and a value at the time of occurrence of each violation may be stored in the array or the list.

The constraint generation unit 22 is a functional unit embodied by the CPU 2 (FIG. 1) of the off-grid area selection device 1 executing the constraint generation program 12 (FIG. 1) stored in the memory 3 (FIG. 1). Based on the off-grid area selection proposal 27 given from the off-grid area selection unit 20 and the system stability violation amount table 34 given from the system stability simulation unit 21, the constraint generation unit 22 generates a constraint expression for the off-grid area to comply with and stabilize the system operation constraint as the system stability constraint 35 for each off-grid area selected by the off-grid area selection unit 20.

Specifically, the constraint generation unit 22 generates a constraint expression for satisfying the following Equation:

$$\begin{matrix}[ Math . 2 ] & \\ y \geq a ( x - b ) + c & ( 2 )\end{matrix}$$

as the system stability constraint 35. In Equation (2), both x and y are optimization variables, y is an estimated value of the system stability violation amount, and x is an off-grid area area. Further, a, b, and c are constants, a is sensitivity information, b is a provisional solution (a value of the optimization variable x in the off-grid area selection proposal 27), and c is a violation amount in the system stability violation amount table 34.

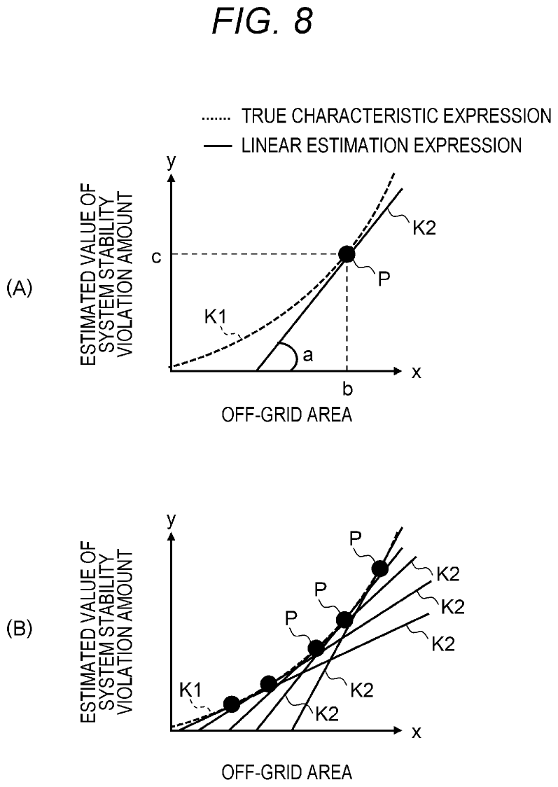

The system stability constraint 35 will be described with reference to FIGS. 8(A) and 8(B). As illustrated in FIG. 8(A), the violation amount for the optimization variable x changes according to a curve K1 representing the true characteristic expression of the violation amount c and the provisional solution b indicated by the dotted line, but it is assumed that the true characteristic expression is unknown. A straight line K2 representing the linear estimation expression indicated by the solid line can also be regarded as a tangent of the curve K1 when the simulation result in the system stability simulation unit 21 is a contact point P. In this simulation result, the value of the x axis coincides with the provisional solution b, and the value of the y axis coincides with the violation amount C.

In the above case, the search range of the estimated value of the stability violation amount c defined by the system stability constraint 35 is the upper left region of the straight line K2, but since the estimated value of the stability violation amount c is minimized by the objective function, in practice, only a line of the straight line K2 is searched. In addition, by generating the system stability constraint 35 in various provisional solutions b, even if the curve K1 is nonlinear, a true characteristic expression can be accurately estimated by superimposing linear characteristic expressions as illustrated in FIG. 8(B).

Of the constants a, b, and c necessary for constituting the system stability constraint 35, values of b and c are received from the off-grid area selection unit 20 and the system stability simulation unit 21, respectively. On the other hand, the value of a representing the sensitivity information is calculated in advance for each condition and held in a table or the like.

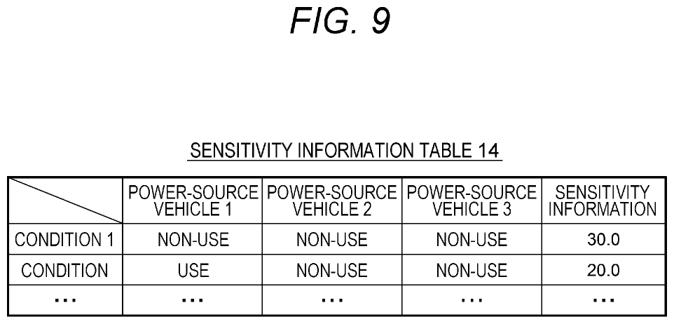

FIG. 9 illustrates a configuration example of a table (hereinafter, referred to as sensitivity information table) 14 for holding preset sensitivity information a. As illustrated in FIG. 9, the sensitivity information table 14 stores values of the sensitivity information a for each condition. FIG. 9 illustrates an example of a case where use/non-use of three power-source vehicles is set as a condition in the off-grid area. For example, it is indicated that the value of the sensitivity information a is “30.0” under a condition that all the three power-source vehicles are not used (“condition 1”), and the value of the sensitivity information a is “20.0” under a condition that only the “power-source vehicle 1” is used and the “power source-vehicle 2” and the “power-source vehicle 3” are not used (“condition 2”). Note that FIG. 9 is an example in a case where whether or not three power-source vehicles are used is a condition, and other conditions may be used.

The constraint generation unit 22 outputs the system stability constraint (constraint expression) 35 generated as described above to the off-grid area selection unit 20. Then, the off-grid area selection unit 20 adds the system stability constraint (constraint expression) 35 to the mathematical programming as a constraint condition, selects an off-grid area again in the same manner as described above, and outputs the selection result to the system stability simulation unit 21 as the off-grid area selection proposal 27. Thereafter, the similar processing is repeated in the system stability simulation unit 21, the constraint generation unit 22, and the off-grid area selection unit 20 until the off-grid area selected by the off-grid area selection unit 20 can comply with the system operation constraint of the power distribution system.

The information finally obtained by the off-grid area selection device 1 by such repetition processing is an off-grid area selection result 36 and an estimation result 37 of the system stability characteristic. Here, the “off-grid area selection result” is the final result of the off-grid area selection proposal 27, that is, the off-grid area selection proposal 27 at the end of calculation. In addition, the “estimation result of the system stability characteristic” is a straight line K2 (linear estimation expression) illustrated in FIG. 8(B), which is a basis for optimality as a solution of the off-grid area selection result and a basis for determination of compliance with the system stability. The off-grid area selection unit 20 outputs the off-grid area selection result 36 and the estimation result 37 of the system stability characteristic finally obtained as described above to the display device 7 (FIG. 1), and displays these pieces of information.

For the off-grid area selection result 36 and the estimation result 37 of the system stability characteristic displayed on the display device 7, when the input device 6 (FIG. 1) is operated and an execution command thereof is input from the operator, the off-grid area selection unit 20 transmits an instruction (hereinafter, referred to as switch operation instruction) to operate a necessary switch to be in an open state to the power distribution automation system 15 (FIG. 1) in order to construct an off-grid in the finally selected off-grid area.

As a result, in the power distribution automation system 15, when each switch designated by the switch operation instruction is operated based on the switch operation instruction given from the off-grid area selection unit 20, the states of these switches are made to transition to the open state. As a result, one or more off-grid areas selected by the off-grid area selection unit 20 are constructed in the power distribution system.

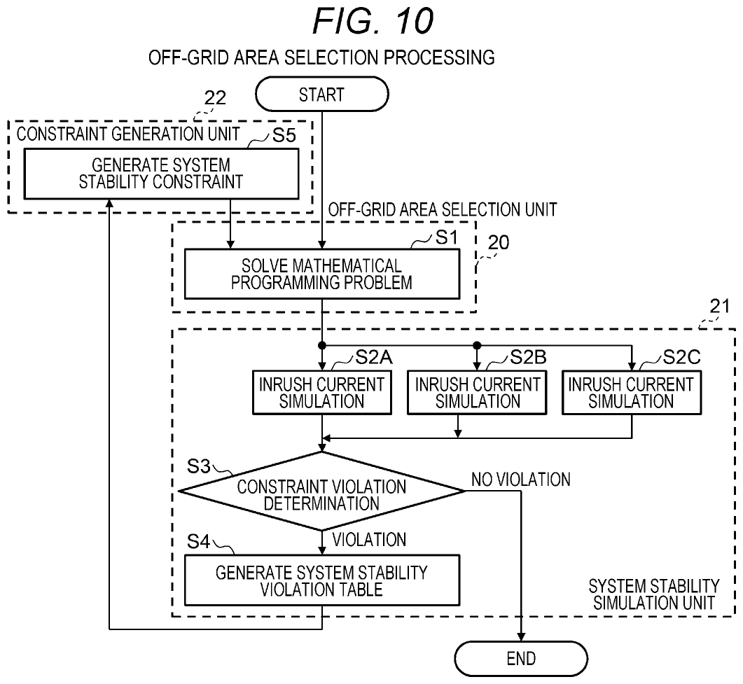

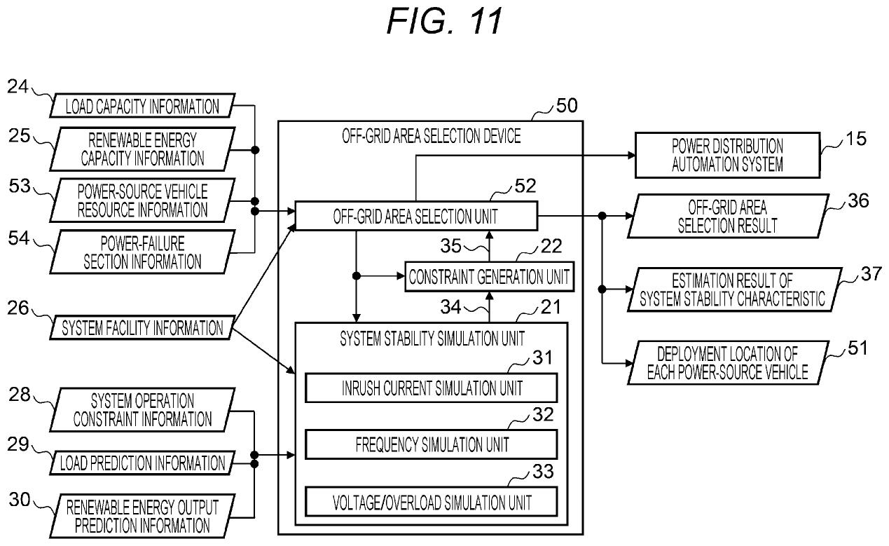

FIG. 10 illustrates a flow of processing up to selection of an off-grid area in a power distribution system (hereinafter, referred to as off-grid area selection processing) among a series of processing executed in the off-grid area selection device 1 of the present embodiment as described above.

This off-grid area selection processing is started when the input device 6 (FIG. 1) is operated in a predetermined manner and an instruction to select an off-grid area is input. Then, first, the off-grid area selection unit 20 acquires the load capacity information 24 (FIG. 2), the renewable energy capacity information 25 (FIG. 2), and the system facility information 26 (FIG. 2) in the power distribution system from the power distribution automation system 15 (FIG. 1), obtains the solution of the mathematical programming problem described above for Equation (1) based on the acquired information, and outputs the obtained solution to the system stability simulation unit 21 as the off-grid area selection proposal 27 (S1).

Subsequently, the system stability simulation unit 21 acquires the system operation constraint information 28 (FIG. 2), the load prediction information 29 (FIG. 2), and the renewable energy output prediction information 30 (FIG. 2) from the power distribution automation system 15, and executes each simulation regarding the inrush current, the frequency variation, the voltage variation, and the overload in each off-grid area selected by the off-grid area selection unit 20 based on the acquired information and the off-grid area selection proposal 27 given from the off-grid area selection unit 20 (S2A to S2C).

Based on the simulation results of these simulations, the system stability simulation unit 21 determines whether or not the off-grid area selected by the off-grid area selection unit 20 violates the system operation constraint (S3).

Then, when none of the off-grid areas finally selected by the off-grid area selection unit 20 satisfies the system operation constraint in any simulation of the inrush current, the frequency, and the voltage/overload (S3: There is a violation), the system stability simulation unit 21 generates the system stability violation amount table 34 (FIG. 7) for each off-grid area finally selected by the off-grid area selection unit 20 as necessary, and outputs the generated system stability violation amount table 34 to the constraint generation unit 22 (S4).

Further, when the system stability violation amount table 34 is given from the system stability simulation unit 21, the constraint generation unit 22 generates the system stability constraint 35 (FIG. 2) satisfying the above Equation (2) based on the system stability violation amount table 34 (S5), and outputs the generated system stability constraint 35 to the off-grid area selection unit 20. Then, the off-grid area selection unit 20 adds the system stability constraint 35 given from the constraint generation unit 22 to the mathematical programming, solves the mathematical programming problem of Equation (1) again, and updates the off-grid area selection proposal 27 that is a solution of the mathematical programming problem (S1).

The above processing in steps S1 to S5 is repeated for at least one off-grid area among the off-grid areas selected by the off-grid area selection unit 20 until there is no constraint violation against the system operation constraint for the system stability constraint.

Then, when at least one off-grid area that does not violate the system operation constraint is eventually selected by the off-grid area selection unit 20 (S3: No violation), the fact is notified from the system stability simulation unit 21 to the off-grid area selection unit 20 via the constraint generation unit 22, whereby the off-grid area is determined as the final off-grid area, and thereafter, the off-grid area selection processing ends.

### (1-2) Effects of Present Embodiment

As described above, in the off-grid area selection device 1 of the present embodiment, the off-grid area selection unit 20 selects an area in which an off-grid in the power distribution system can be constructed based on the load capacity information 24, the renewable energy capacity information 25, and the system facility information 26 for each switch section, and the system stability simulation unit 21 simulates the system stability in the off-grid area selected by the off-grid area selection unit 20, and determines whether or not the area can comply with the system operation constraint of the power distribution system.

Therefore, according to the off-grid area selection device 1, it is possible to simulate the system stability only for the area where the off-grid can be constructed, and thus, it is possible to select the off-grid area in consideration of the system stability in a short time.

### (2) Second Embodiment

In the present embodiment, a case where an off-grid area is selected in an emergency such as a power failure will be described. Here, it is assumed that solar power generation, a system storage battery, and a power-source vehicle are used as the power source of the off-grid area.

FIG. 3, in which parts corresponding to those in FIG. 2 are denoted by the same reference numerals, illustrates a logical configuration of an off-grid area selection device 50 according to the second embodiment. Since the hardware configuration and the software configuration of the off-grid area selection device 50 are similar to those of the first embodiment, the description thereof will be omitted here.

The off-grid area selection device 50 is different from the off-grid area selection device 1 of the first embodiment in that a deployment location 51 of each power-source vehicle is presented in addition to the off-grid area selection result 36 and the estimation result 37 of the system stability characteristic as a final result.

In practice, in the case of the off-grid area selection device 50 of the present embodiment, an off-grid area selection unit 52 acquires power-source vehicle resource information 53 and power-failure section information 54 in addition to the load capacity information 24 and the renewable energy capacity information 25 from the power distribution automation system 15 (FIG. 1). The power-source vehicle resource information 53 is information on each power-source vehicle, and includes information on the power generation capacity of each power-source vehicle and a deployment location in advance. The power-failure section information 54 is information indicating a switch section in which a power failure has occurred due to a disaster or the like.

Then, the off-grid area selection unit 52 solves the mathematical programming problem described above for Equation (1) based on the acquired information. At this time, the off-grid area area “area” of Equation (1) is defined as the area of the off-grid area in the area where the power failure occurs, which is obtained as the power-failure section information 54. In addition, the constraint condition of the mathematical programming problem includes the upper limit of the number of power-source vehicles, the power generation capacity of each power-source vehicle, and the like in addition to the constraint expression of the mathematical programming. Furthermore, as the optimization variable of the mathematical programming problem, in addition to the above-described optimization variables x and y of the mathematical programming, a deployment location of each power-source vehicle and the like are included. The system stability simulation unit 21 and the constraint generation unit 22 other than the off-grid area selection unit 52 execute processing similar to that of the off-grid area selection device 1 of the first embodiment.

As a result, in the off-grid area selection device 50, as a final solution of the mathematical programming problem solved by the off-grid area selection unit 52, an off-grid area selection result 36 representing one or a plurality of areas (off-grid areas) that can be turned into an off-grid in an area where a power failure has occurred, an estimation result 37 of the system stability characteristic for each off-grid area, and a deployment location 51 of each power-source vehicle are obtained, and these pieces of information are displayed on the display device 7 (FIG. 1).

As described above, according to the off-grid area selection device 50 of the present embodiment, since it is possible to select an off-grid area in an emergency such as a power failure, in addition to the effect obtained by the first embodiment, it is also possible to obtain the effect of reducing the power failure time and improving the resilience of the power distribution system.

### (3) Other Embodiments

Note that, in the first and second embodiments described above, the case where the off-grid area selection device according to the present invention is constructed by one server device has been described, but the present invention is not limited thereto, and the functions of the off-grid area selection device may be distributed and arranged in a plurality of computer devices constituting a distributed computing system.

In the first and second embodiments described above, the inrush current simulation unit 31, the frequency simulation unit 32, and the voltage/overload simulation unit 33 are provided in the system stability simulation unit 21. However, the present invention is not limited to this, and the system stability simulation unit 21 may be provided with a functional unit that performs a simulation regarding system stability other than this.

Furthermore, in the first and second embodiments described above, as the information regarding the power supply facility for each switch section, the information regarding the renewable energy (the renewable energy capacity information 25) output from the renewable energy power generation facility or the like existing in the switch section is acquired for each switch section. However, the present invention is not limited to this, and information regarding an independent power supply facility that can be a power source of the off-grid area even if the power supply facility is other than the renewable energy may be acquired and used for selection of the off-grid area.

Furthermore, in the second embodiment described above, the case where only the function of selecting the off-grid area in an emergency such as a power failure is mounted on the off-grid area selection device 50 has been described, but the present invention is not limited thereto, and all the functions of the off-grid area selection device 1 of the first embodiment may be mounted on the off-grid area selection device 50 of the second embodiment in addition to the functions of the second embodiment described above.

### INDUSTRIAL APPLICABILITY

The present invention can be applied to an off-grid area selection device that selects an area where an off-grid in a power distribution system having a plurality of switches arranged therein can be constructed.

### REFERENCE SIGNS LIST

1, 50 off-grid area selection device
2 CPU
6 input device
7 display device
14 sensitivity information table
15 power distribution automation system
20, 52 off-grid area selection unit
21 system stability simulation unit
22 constraint generation unit
24 load capacity information
25 renewable energy capacity information
26 system facility information
27 off-grid area selection proposal
28 system operation constraint information
29 load prediction information
30 renewable energy output prediction information
31 inrush current simulation unit
32 frequency simulation unit
33 voltage/overload simulation unit
34 system stability violation amount table
35 system stability constraint
36 off-grid area selection result
37 estimation result
38 switch
51 deployment location

1. An information processing device that selects an area in which an off-grid in a power distribution system having a plurality of switches arranged therein is constructible, the information processing device comprising:
an off-grid area selection unit that selects an area in which the off-grid in the power distribution system is constructible based on each piece of information regarding a load capacity and a power supply facility for each switch section and facility information of the power distribution system; and
a system stability simulation unit that simulates system stability in the area selected by the off-grid area selection unit and determines whether or not the area is able to comply with a system operation constraint of the power distribution system.

2. The information processing device according to claim 1, further comprising a constraint generation unit that generates a constraint for the area to comply with the system operation constraint when the area selected by the off-grid area selection unit is unable to comply with the system operation constraint of the power distribution system,
wherein until the area selected by the off-grid area selection unit complies with the operation constraint of the power distribution system, the off-grid area selection unit repeats a process of adding the constraint generated by the constraint generation unit and selecting the area in which the off-grid in the power distribution system is constructible, a process of simulating the system stability in the area by the system stability simulation unit, and a process of generating the constraint for the area to comply with the system operation constraint by the constraint generation unit.

3. The information processing device according to claim 2, wherein the off-grid area selection unit outputs an estimation result of system stability in the area in addition to a selection result of the area in which the final off-grid is constructible.

4. The information processing device according to claim 2, wherein the off-grid area selection unit transmits an instruction to open or close the necessary switch to a system of a company that operates the power distribution system in order to construct the off-grid in the finally selected area.

5. An information processing method executed by an off-grid area selection device that selects an area in which an off-grid in a power distribution system having a plurality of switches arranged therein is constructible, the method comprising:
a first step of selecting an area in which an off-grid in the power distribution system is constructible based on each piece of information regarding a load capacity and a power supply facility for each switch section and facility information of the power distribution system; and
a second step of simulating system stability in the selected area and determining whether or not the area is able to comply with a system operation constraint of the power distribution system.

6. The information processing method according to claim 5, further comprising a third step of generating a constraint for the selected area to comply with the system operation constraint when the selected area is unable to comply with the system operation constraint of the power distribution system,
wherein the first to third steps are repeated until the area selected in the first step complies with the operation constraint of the power distribution system.

7. The information processing method according to claim 6, further comprising a fourth step of outputting an estimation result of system stability in the area in addition to a selection result of the area in which the final off-grid is constructible.

8. The information processing method according to claim 2, wherein in the fourth step, the off-grid area selection device transmits an instruction to open or close the necessary switch to a system of a company that operates the power distribution system in order to construct the off-grid in the finally selected area.
